(19) United States
(12) Patent Application Publication
(10) Pub. No.: US 2006/0116001 A1
(43) Pub. Date: Jun. 1, 2006

(54) Patterning method

(76) Inventor: Xiangjun Wang, Linkoeping (SE)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 10/519,899

(22) PCT Filed: Jul. 7, 2003
(86) PCT No.: PCT/GB03/02917

§ 371 Date: Aug. 22, 2005

(30) Foreign Application Priority Data
Jul. 9, 2002 (GB) 0215858.2

(51) Int. Cl. H01L 21/26; H01L 21/324; H01L 21/42; H01L 21/477

(52) U.S. Cl. 438/798

(57) ABSTRACT

A method for patterning a device layer, for example of an organic electronic or optoelectronic device, using a patterned stamp. The method comprising the steps of (a) providing a substrate, (b) bringing the patterned stamp into contact with the substrate, (c) removing the patterned stamp from the substrate, characterized in that step (b) is carried out so that the surface energy of the substrate is modified in accordance with the pattern, and that the method further comprises a step (d) depositing a solution of a device layer on the substrate after the patterned stamp has been removed, whereby the surface energy of the substrate determines the deposition pattern of the device layer.

The present invention relates to a method for patterning a device layer and to devices made using the method. The invention is particularly concerned with a method for patterning an optoelectronic device layer that is simpler and more cost effective than previously known methods.

One class of optoelectronic device that is of particular interest of the present invention is an organic light-emitting device (OLED). These devices employ an organic material for emission.

Polymers are an attractive choice for use in OLED devices. For example, WO 90/13148 describes such a device comprising a semiconductor layer comprising a polymer film that comprises at least one conjugated polymer situated between electrodes. Other polymer layers capable of transporting holes or transporting electrons to the emissive layer may be incorporated into such devices.

In a typical OLED device, the anode electrode typically is a layer of transparent indium-tin oxide (ITO). The ITO typically is covered with at least a layer of a thin film of an electroluminescent organic material. A hole transport layer may be provided between the ITO and the organic material. A final layer forming a cathode electrode, which is typically a metal or metal alloy covers the organic material.

In order to fabricate the device structure, various techniques for fabricating nano structures have been developed. To obtain functional devices it often is necessary to pattern the active device layers and the electrodes.

Organic light emitting devices (OLED's) which make use of thin films of polymer are becoming an increasingly popular technology for applications in devices comprising a plurality of OLED pixels arranged to form a display, such as a flat panel display (FPD). Such an OLED including a pixel arrangement typically comprises a plurality of luminescent pixels that are arranged in a matrix form.

To form an array of OLED's, constituent materials must be patterned. A pixelated OLED device includes, for example, a plurality of first electrode strips formed on a substrate. The strips are arranged in a first direction. One or more organic layers are formed on the first electrode strips. A plurality of second electrode strips is formed over the organic layers in a second direction that typically is orthogonal to the first direction. The intersections of the first and second electrode strips form pixels.

Patterning active device layers and electrodes previously has been done using standard photolithography processing.

Standard photolithography processing typically involves photolithographic and etching techniques. Photolithographic techniques all share the following operational principal;

exposure of an appropriate material to electromagnetic radiation in order to introduce a latent image into the material as a result of a set of chemical changes in its molecular structure;

subsequent developing of the latent image into relief structures through chemical etching.

Patterning of the latent image can be achieved by interposing a mask between the source of radiation and the material. When masks are used, the lithographic process yields on the material a replica of the pattern on the mask.

This method commonly has been used to produce a patterned anode on a substrate, for example ITO tracks on a glass substrate. For example, a photosensitive resist layer is deposited as a layer on an anode layer. The resist layer is exposed with radiation having the desired pattern defined by a mask. After development, unwanted resist is removed to expose portions of the anode beneath. The exposed portions are removed by a wet etch, leaving the desired pattern on the anode layer. Cathode strips may be created similarly. It can be seen that this conventional technique requires numerous steps, increasing raw process time and manufacturing costs.

Several problems have arisen in the chemical etching of some materials and the chemical compatibility of some materials with conventional photoresists. Particularly, standard photolithography processing is not suitable for some polymers because the surface could be exposed to solvents or UV light, which might cause material degradation. Thus, it has been considered that there is a need to develop special patterning techniques for polymers. It therefore has been considered desirable to pattern conducting electrodes and semiconducting polymers in devices with non-photolithographic techniques.

One alternative to photolithography is soft lithography. This is the collective name for a set of lithographic techniques using a patterned elastomer stamp to generate or transfer the pattern. Soft lithography patterning techniques are based on physical contact, not the projection of light through a mask, as in photolithography. Soft lithography offers immediate advantages over photolithography for applications in which patterning non-planar substrates, unusual materials, or large area patterning are the major concerns. As described in Advanced Materials 2000, 12 No. 4 page 269 to 273, there are several advantages of using soft lithography compared to conventional photolithography: it is less costly, has no optical diffraction limit, allows control of the chemistry of a patterned surfaced, does not expose the sample to high-energy radiation and can easily be applied to non-planar surfaces. Soft lithography is a gentle process that therefore is of great interest for patterning sensitive materials such as polymers.

Soft lithography includes microcontact printing (μCP); replica moulding, self assembled monolayers; put-down and lift-up; and micromoulding in capillaries (MIMIC) techniques.

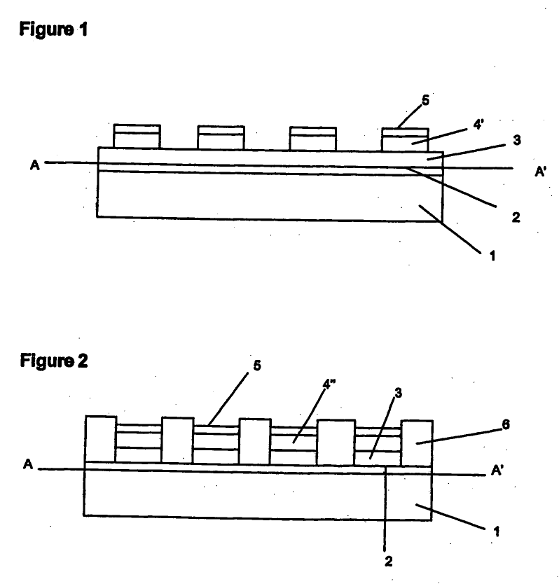

A replica moulding (soft embossing) technique is summarised in FIG. 1 of Advanced Material 2000, 12 No. 3 page 189 to 195. A patterned elastomer is put in conformal contact with an active polymeric film area and the assembly is brought to the polymer softness transition temperature. After cooling, the patterned elastomer stamp is removed and leaves the grating pattern on the polymer surface. This technique also is generally described in FIG. 3(A) of Chemical Reviews 1999, Vol. 99 No. 7 page 1823 to 1848.

Three different general methods of soft lithography are summarised in FIG. 1 on page 270 of Advanced Materials 200, 12 No. 4. It can be seen that, in general, microcontact printing and lift-up both involve a transfer of polymer material either from the rubber stamp to the substrate or from the substrate to the rubber stamp. The MIMIC technique necessitates introducing polymer material into capillaries that are formed when the stamp is in conformal contact with the substrate.

The specific disclosure of this document is limited to microcontact printing of PEDOT-PSS onto ITO substrate; microcontact printing of PEDOT-PSS onto gold substrate; lift-up of PEDOT-PSS on glass substrate and micromoulding in capillaries of polyurethane. The MIMIC method was used to pattern the thermally evaporated aluminium cathode and the other two methods patterned the anode. Electrically separated anode lines were achieved by putting PEDOT-PSS onto gold and, through wet etching, removing the gold between the PEDOT-PSS lines.

WO 01/04938 provides an alternative to conventional photolithographic and etching techniques. The method is a stamping or embossing method and uses a stamp made of a hard material such as steel, silicon, or ceramic. A pattern is defined by protrusions on the surface of the stamp. A load is applied on the stamp forcing the stamp against the substrate.

This causes the pattern on the stamp to be transferred to the substrate.

A specific lift-up technique is described in WO 01/39288. This document relates to patterning an electrode layer using a silicon stamp. The patterned stamp is coated with an adhesive material such as a metal. The patterned stamp is removed such that the portions of the electrode layer in contact with the raised portions of the stamp are removed with the stamp.

As acknowledged in WO 00/70406, the stamp material used in many soft lithography techniques is problematic when used in combination with polymers solvated in some organic solvents such as isopropanol, xylene, chloroform or water. Isopropanol, xylene and chloroform prevent the patterning of many polymers because these solvents can swell the stamp and destroy the fine pattern to be transferred. Alternatively, the patterning of water-soluble polymers prohibits the use of some soft lithography techniques such as MIMIC as water is not easily transported through the extremely non-polar elastomeric stamp.

In order to address this problem, WO 00/70406 provides a method for patterning a polymer film that involves depositing onto a material surface a thin film of polymer, applying to the material surface a stamp made of an elastomeric material in conformal contact with the surface of the thin film. Portions of the thin film contact one or more protruding elements of the elastomeric stamp and are attached to the protruding element. These portions are removed from the material surface with the stamp. In the method, no solvent is used. The method can be considered to be a “lift-up” soft lithography method. An equivalent “put-down” method to the “lift-up” method also is described in this document.

An alternative method is to combine soft lithography with the self-assembled monolayer technique. A hydrophilic monolayer pattern residing on a hydrophobic background, or a hydrophobic monolayer pattern residing on a hydrophilic background, will direct polymer solutions on the surface to selectively wet and spread on one of these regions, and finally a duplicated polymer pattern forms after solvent evaporation. This method can be controlled by the liquid and solid surface free energy. However, the method requires suitable monolayer material being transferred to a patterned area, which is probably unwanted in the final structure. The chemical step involved in the transfer of the self-assembled monolayer also influences the final properties of the patterned film.

In parallel with the above mentioned soft lithography techniques for fabricating patterned nano structures, in recent years, technology has been under development for obtaining functional devices by forming prescribed patterns by applying thin films having different properties onto different zones on the same substrate. However, a problem arises at the process surface in that the different thin film materials become mixed on the substrate. This is because the liquid material that is discharged into one zone on the substrate flows over into adjacent zones. What is commonly done to overcome problems such as this is to provide protruding portioning members (called “banks” or “rises”) to partition off different thin film zones and then to fill the areas enclosed by these portioning members with the liquid materials constituting the different thin films. In the context of a pixelated OLED device, banks may be provided to partition off the various pixels.

The use of banks is described in EP 0880303. In EP 0880303, it is stated that in order to realize a full colour display device, it is necessary to arrange organic luminescent layers that emit any one of red, green and blue for the respective pixels. It is further stated that a problem with this is that it is difficult to carry out patterning with high precision. As such, EP 0880303 provides banks to fill the spaces between the pixel electrodes to prevent mixing of colours of the luminescent materials.

EP 0989778 is also concerned with thin film formation technology that uses banks. The method aims to overcome problems with existing bank technology and involves subjecting the banks to a surface treatment under conditions such that the degree of non-affinity exhibited by the banks for the liquid thin film material is modified by deposition of chemical groups such as CF groups on the surface of the banks. Reduced pressure plasma treatments and atmospheric pressure plasma treatments are mentioned. Further, a combination of oxygen plasma treatment and fluorine-based gas plasma treatment is mentioned. The method does not use a stamp.

It will be appreciated that the use of banks complicates the process of manufacturing a device and thus makes it less time and cost effective.

Therefore, it is an object of the present invention to provide a simplified but effective method for patterning a device layer.

Accordingly, in a first aspect of the present invention, there is provided a method for patterning a device layer using a patterned stamp comprising steps of:

(1) providing a substrate;

(2) bringing the patterned stamp into contact with the substrate

(3) removing the patterned stamp;

characterised in that step (2) is carried out so that the surface energy of the substrate is modified in accordance with the pattern; and that the method further comprises a step;

(4) depositing a solution of a device layer on the substrate after the patterned stamp has been removed, whereby the surface energy of the substrate determines the deposition pattern of the device layer.

The method provides a convenient way to build (polymer) microstructures for application in (polymer) microelectronics device using methods such as spin coating or dip coating. Such microstructures may be, for instance, passively addressed (polymer) light emitting diodes (LEDs) with pixels in micro feature size.

It will be appreciated from the above that, in step (2) of the method according to the first aspect of the present invention, bulk material is not transferred either from or to the surface of the patterned stamp. This has a clear advantage over known soft lithography methods that use a patterned stamp and where bulk material is transferred from or to the patterned stamp in the soft lithography method. Namely, in the present method, the patterned stamp will not be contaminated during use. Thus, the patterned stamp can be used again and, more specifically, can be used again without subjecting it to costly and yet somewhat still unreliable cleaning methods. A further advantage is that the surface of the substrate also is not contaminated during the method.

In contrast with some soft lithographic methods, it will be understood also that the patterned stamp per se is brought into contact with the substrate in the method according to the first aspect of the present invention. In most soft lithography methods, the stamp is not brought into direct contact with the substrate. Instead, a layer of device layer material always is interposed between the stamp and the substrate. In the present invention the stamp is brought into direct contact with the substrate with no intervening layer of material between the stamp and the substrate and with no bulk transfer of material between the stamp and the substrate. As compared with some soft lithography methods, it will be appreciated readily that any problems of incompatibility between the stamp material and device layer solvent are obviated in the present method because the device layer is deposited after the patterned stamp has been removed.

The key to the present method is effective modification of the surface energy of portions of the surface of the substrate. It will be appreciated from the above that soft lithography methods do not involve at all modification of surface energy of the substrate itself.

Further, it will be appreciated that no banks are needed in the method according to the first aspect of the present invention. This is because the deposited device layer is confined to portions of the surface of the substrate by virtue of the difference in surface energy between these portions and the remainder of the surface of the substrate. The ability to omit the use of banks in the method according to the first aspect of the present invention greatly simplifies the method and, thus, makes it more time and cost effective. The present invention provides an alternative and much more simple solution to at least some of the problems of previously known methods.

For the purposes of the present invention, the term “patterned stamp” may be taken to mean a stamp having one or more protruding elements such that when the patterned stamp is brought into contact with the substrate in step (2), the one or more protruding elements are in contact with the surface of the substrate and one or more indentations (between the one or more protruding elements) will not be in contact with the surface of the substrate.

For the purposes of the present invention, the term “device layer” may be taken to encompass any layer of material suitable for inclusion in an electrical, mechanical or electromechanical device. As such, layers of bank material are intended to be encompassed by this term.

In the present invention, “surface energy” is measurable by contact angle measurements. Generally, contact angles are measured on model surfaces.

In the present invention, preferably, the patterned stamp is a patterned elastomer. As such, any reference to a patterned stamp in the context of the present invention preferably is a patterned elastomer.

Preferably, in step (2), the patterned stamp is brought into conformal contact with the surface of the substrate.

It is preferable in the present method that the morphology and/or topography of the surface of the substrate is unchanged, particularly substantially or completely unchanged, after the patterned stamp has been brought into conformal contact with the substrate in step (2) This is measurable by atomic force microscope (AFM) measurements.

Generally, step (2) is carried out under conditions and for a sufficient time so that the surface energy of the substrate is modified in accordance with the pattern. In this regard, step (2) is carried out under conditions and for a sufficient time so that the surface energy of either (i) any portion of the surface of the substrate that is in contact with the patterned stamp or (ii) any portion of the surface of the substrate that is not in contact with the patterned stamp is modified.

In step (2), the surface energy of the portion of the surface of the substrate that is in contact with the patterned stamp may be increased or decreased. Alternatively, the surface energy of the portion of the surface of the substrate that is not in contact with the patterned stamp may be increased or decreased.

On the substrate, after deposition of the device layer in step (4), the device layer is either (i) only on portions of the surface of the substrate that were in contact with the patterned stamp or (ii) only on portions of the surface of the substrate that were not in contact with the patterned stamp.

It will be appreciated that to a large extent it is the difference in surface energy between portions of the surface of the substrate that were in contact with the patterned stamp and the remainder of the surface of the substrate (which difference may be positive or negative) that will determine whether, after deposition, the device layer is either only on portions of the surface of the substrate that were in contact with the patterned stamp or only on portions of the surface of the substrate that were not in contact with the patterned stamp.

Preferably, the device layer comprises an organic material. In this regard, the present method is particularly advantageous when the device layer comprises an organic polymer. This is because of the difficulties incurred with previously known methods when the device layer to be patterned comprises a polymer, as discussed above. Conjugated polymers solvated in a non-polar organic liquid selectively wets and spreads over an area with higher surface energy, but dewets and retracts from the area with lower surface energy. The polymer solution is confined to the high surface energy area, and finally deposits by evaporation of the solvent, and eventually generates a pattern on the surface. Wetting and dewetting properties of the solution are dependent on the properties of the solvent per se. As such, a non-polymeric material dissolved in a particular solvent would behave similarly to a polymeric material dissolved in the same solvent, having regard to wetting and dewetting properties.

Particularly where the device layer is a part of an OLED or plastic transistor (although not so limited), the polymer preferably is electrically conductive or semi conductive, more preferably conductive. Also preferably, the polymer is at least partially, substantially, or even fully conjugated. Also preferably, the device layer is soluble in a solvent selected from the group consisting of xylene, ortho-xylene, toluene, benzene, mesitylene, chloroform, dichloromethane or mixtures thereof.

A solution of the device layer is deposited on the substrate in step (4). As such, deposition technique and droplet size also may be selected so as to optimise the effect of the device layer being deposited either only on portions of the surface of the substrate that were in contact with the patterned stamp or only on portions of the surface of the substrate that were not in contact with the patterned stamp.

Suitable deposition techniques include spin coating, inkjet printing, dip coating and screen printing. Spin coating and inkjet printing are preferred and inkjet printing is most preferred. In each of these techniques, the device layer may be deposited over the whole of the surface of the substrate. However, after deposition, the device layer will be either only on portions of the surface of the substrate that were in contact with the patterned stamp or only on portions of the surface of the substrate that were not in contact with the patterned stamp. This is because of the difference in surface energy between these portions and the remainder of the surface of the substrate. The difference in surface energy will cause the device layer material to flow either only to portions of the surface of the substrate that were in contact with the patterned stamp or only to portions of the surface of the substrate that were not in contact with the patterned stamp.

The final pattern, controlled by surface free energy, duplicates the stamp pattern either positively or negatively.

The polarity of any solvent may be selected so as to enhance the effect of the device layer being deposited either only on portions of the surface of the substrate that were in contact with the patterned stamp or only on portions of the surface of the substrate that were not in contact with the patterned stamp. In some cases, it may be preferable for the solvent to be significantly non-polar. Generally, light-emitting polymers are deposited from non-polar solvents such as xylene. PEDOT and polyaniline generally are deposited from polar solvents such as water.

Preferably, the solvent is an organic solvent and, more preferably, is selected from the group consisting of xylene, ortho-xylene, trimethylbenzene, toluene, benzene, mesitylene, chloroform, dichloromethane and mixtures thereof.

The environment in which depositing in step (4) occurs can be optimised in order to optimise the effect of the device layer being deposited either only on portions of the surface of the substrate that were in contact with the patterned stamp or only on portions of the surface of the substrate that were not in contact with the patterned stamp. Temperature, atmospheric humidity and atmospheric pressure all should be considered.

As stated above, the patterned stamp must be brought into contact with the substrate. This may be achieved simply by placing and leaving the patterned stamp on the surface of the substrate by any suitable means.

The thickness of the deposited device layer also may affect the effectiveness of the present method. It is usual that the thickness of the deposited device layer is up to 2000 Å. Preferably, an electrode device layer may have a thickness in the range 1000 to 2000 Å, more preferably about 1500 Å. Other device layers such as an emissive layer in an OLED preferably have a thickness of up to 1000 Å.

It has been found that faithful reproduction of the pattern on the patterned stamp on the surface of the substrate is achievable. In particular, faithful reproduction has been achieved where the feature size of the pattern can be varied from 20 microns to 500 microns with a resolution of a few microns. Feature sizes in this range are suitable for forming a device layer in an OLED.

Modification of the surface energy in step (2) of the present method may be a transient effect. As such, step (4) must be carried out, in the present method while the effect still is strong enough to result in a patterned device layer. Accordingly, it is preferred that step (4) is carried out directly after step (3), more preferably immediately after.

In a first embodiment of the present method, in step (2), the surface energy of any portion of the substrate that is in contact with the patterned stamp is modified. This modification may be, for example, by transfer of chemical groups (i) from the surface of the patterned stamp to any portion of the surface of the substrate that is in contact with the patterned stamp and/or (ii) from any portion of the surface of the substrate that is in contact with the patterned stamp to the surface of the patterned stamp. Also, this modification may be by rearrangement of chemical groups on the surface of any portion of the surface of the substrate that is in contact with the surface of the patterned stamp. Infrared reflection-absorption spectroscopy (IRAS), can be carried out in order to chemically characterize the modified surface of the substrate and also the surface of the patterned stamp.

In this embodiment, the modification of the surface energy by contact with the patterned stamp is the most crucial step during the patterning procedure; the interfacial surface free energy between device layer (usually a polymer solution) and the patterned stamp is the essential driving force controlling the patterning.

According to the first embodiment of the first aspect of the present invention, the patterned stamp has a function to modify the surface energy of the substrate, typically a film formed from aqueous solution. No additional surface energy modifying process is needed. As the patterned stamp is applied on a substrate surface for a time period it can turn some surfaces from high surface energy to low surface energy and can turn other surface from low surface energy to high surface energy. The change in surface energy is attributed to the interaction between the stamp surface (usually elastomer molecules) and the substrate surface. The formation of either a positive pattern or a negative pattern can be understood by the requirement of minimization of free energy of whole system. Surface energy directs liquid to the high surface energy area where contact angle is lower. Liquid easily wets and spreads over the area and finally deposits on the hydrophobic area after the solvent evaporates. A pattern generated in a positive or a negative manner with respect to the patterned stamp depends on modification effect. A positive pattern can be formed when the patterned stamp modifies a surface from low surface energy to high surface energy. A negative pattern can be generated when the patterned stamp modifies a surface from high surface energy to low surface energy. Patterning of polymer on a modified PEDOT-PSS surface by spin coating, for example, demonstrates the very strong adhesive force between polymer solution and high surface energy area. The larger difference in surface energy or in contact angle is indeed a crucial rule for the patterning procedure.

It will be appreciated that the stamp material may be selected so as to optimise the surface energy modifying effect in the first embodiment of the present method. In this embodiment, it is preferred that the stamp is an elastomer and a particularly preferred elastomer is poly(dimethylsiloxane)(PDMS) and equivalents thereof. PDMS is solvent resistant and is soft and flexible with a low surface energy such that it may easily be removed from the substrate. Further, it has been found that particularly good resolution can be obtained using PDMS as the patterned elastomer. Specifically, resolution has been found to improve threefold over previous photolithography methods for patterning a device layer.

Further, it will be appreciated that the substrate material may be selected so as to optimise the surface energy modifying effect in the first embodiment of the present method.

To this end, in the first embodiment of the present method, it is preferred that the substrate is polar. Specifically, it is preferred that the substrate material includes charged groups, more preferably charged groups such as sulfate, carboxylate etc.

The present method is particularly advantageous when the substrate comprises a polymer, preferably an electrically conductive or semiconductive polymer. More preferably, the polymer is at least partially, substantially, or even fully conjugated.

The polymer advantageously is a charge transporting polymer or a charge injecting polymer, optionally with a negatively or positively charge dopant. The charged dopant may be used to enhance the patterning effect. More advantageously, the polymer is selected from the group consisting of poly (3,4-ethylenedioxythiophene) (PEDOT), poly (3,4-ethylenedioxy-thiophene)-poly(styrenesulfonate) (PEDOT-PSS), polyaniline with acid dopant and polyaniline-PSS. It is most preferred that the substrate is PEDOT on a layer of ITO.

In this embodiment, it is preferred that the patterned stamp is brought into contact with the surface of the substrate at room temperature and at ambient humidity. In this regard, the temperature should be such that the thermal energy of the substrate is not great enough to overcome any surface modification due to contact with the patterned stamp.

Further, in this embodiment, it will be appreciated that the modification of the surface energy is due to inherent properties of the patterned stamp and substrate material. It will be a time dependent effect. Thus, it is preferred that the patterned stamp is in contact with the substrate for a period of time sufficient to allow this effect to proceed to completion/its maximum. Typically, this period will be longer than one day or more typically longer than two days and most typically up to several days.

In a second embodiment of the present method, in step (2) the surface energy of any portion of the substrate that is not in contact with the patterned stamp is modified. In this embodiment, the patterned stamp is used as a mask in step (2) and step (2) includes subjecting any portion of the surface of the substrate that is not in contact with the patterned stamp to a surface energy modifying process. Any suitable surface energy modifying process known in the art may be used so long as it produces the desired effect. Suitable surface energy modifying processes include exposure to UV radiation, plasma treatment.

The second embodiment of the present method will be particularly useful when the substrate material is not responsive to surface modification merely by bringing a patterned stamp into contact with the substrate. A notable substrate material in this regard is indium tin oxide, a common material used for the anode in OLEDs.

In the second embodiment, O₂/CF₄ plasma treatment may be carried out in a RF barrel etcher of dimensions about 300 mm diameter, about 450 mm depth, with a gas mixture of about 0.5-2% CF₄ in oxygen, at a pressure of about 1.5 Torr and a power of about 400 W. The treatment suitably is carried out for about 10-30 s. In the case of exposure to UV radiation, the UV light source may be an Ushio UER 200-172 lamp providing 7 mW/cm² at a wavelength of 172 nm. Suitably, the UV light source may be positioned about 1.1 mm from the substrate. The treatment suitably is carried out for about 15 s.

In the second embodiment, it is preferred that the stamp is an elastomer and a particularly preferred elastomer is poly(dimethylsiloxane)(PDMS) and equivalents thereof.

In a second aspect according to the present invention, there is provided a method for making an electrical, mechanical, or electromechanical device including a method according to the first aspect of the present invention.

In this second aspect of the present invention, the substrate provided in step (1) typically will be supported by one or more further device layers, at least one of which may be a patterned device layer. Also, typically, the method according to the second aspect of the present invention will include a further step (5) of depositing on the device layer deposited in step (4) one or more further device layers.

Preferably, the method according to the second aspect is a method for manufacturing an optoelectronic device, more preferably, the optoelectronic device is selected from an OLED, specifically a pixelated OLED, a transistor, a solar cell, a photodiode, a diffraction grating, a microcircuit, specifically a printable microcircuit, and a microfluidic device.

An important pixelated OLED device is a flat panel display (FDP). The FPD may be used in products including cellular phones, cellular smart phones, personal organisers, pagers, advertising panels, touch screen displays, teleconferencing equipment, virtual reality products, and display kiosks.

The method according to the second aspect of the present invention provides a convenient way to, build polymer microstructure for application in polymer microelectronics device, like passively addressed polymer light emitting diodes, (LEDs) displays, optically pumped micro-patterned polymer micro cavities and field effect transistors (FETs).

A method for manufacturing a monochrome OLED device is described generally below:
Provide a transparent, typically glass, substrate
Provide an anode layer, typically ITO, on the transparent substrate where the anode is patterned in parallel lines. This may be achieved using photolithographic and etching techniques
Deposit a layer of polymer, for example a semiconductive polymer such as a hole transport polymer (e.g. PEDOT-PSS), on the anode layer by a suitable deposition technique such as spin coating
Bring a patterned stamp into contact with the semiconductive polymer layer, the pattern of the patterned stamp being such that the surface of the semiconductive polymer layer is modified in lines orthogonal to the parallel anode lines
Spin coat or inkjet print a device layer, such as a light-emissive polymer, on the semiconductive polymer layer. After deposition, the polymer will be in parallel lines (orthogonal to the ITO parallel lines) in accordance with the pattern of the patterned stamp
Deposit cathode material in parallel lines that also are orthogonal to the ITO parallel lines. This may be carried out by a masking technique.

In the above general method, it will be appreciated that a patterned stamp according to the present invention also may be used to pattern the anode and the cathode, provided that the anode or cathode can be deposited from solution. Also, it will be appreciated that further device layers, other than those explicitly referred to, may be provided. The further device layers may be selected from hole transport layers and electron transport layers and also may be patterned using a patterned stamp according to the present invention.

The above method may be modified for the preparation of a colour device. Instead of the patterned stamp being patterned so that parallel lines of spin-coated polymer are formed, the patterned stamp should be patterned so that the surface energy of the polymer is modified in accordance with a well or pixel structure. Red, Green and Blue light-emitting polymers then can be inkjet printed into the wells as required.

Cathode then can be deposited in accordance with the monochrome device above.

The above descriptions of monochrome and colour device structures are intended to be examples only. Those skilled in the art will readily appreciate modifications in accordance with this invention that could be made to these device structures.

According to a fourth aspect of the present invention, an electrical, mechanical or electromechanical device is provided as defined above in relation to the second aspect of the present invention. Suitably, the device may be obtained by the method according to the second aspect of the present invention. The device contains at least a patterned device layer supported on a substrate.

In devices according to the fourth aspect of the present invention, the surface of the substrate that is in contact with the patterned device layer is substantially flat, without relief features. This may be contrasted with some prior art devices where “banks” are used to create relief features on the surface of the substrate.

Regions of patterned device layer in devices according to the fourth aspect of the present invention are not separated by physical means.

Preferably, the patterned device layer comprises a polymer.

Also preferably, the substrate is charged and/or comprises a polymer.

One or more further device layers may be supported on the patterned device layer and/or the substrate may be supported on one or more further device layers, as required. One or more of the further device layers may be patterned, as required.

Preferably, the electrical, mechanical or electromechanical device is an optoelectronic device. More preferably, the optoelectronic device is selected from the group consisting of an OLED, a transistor, a diffraction grating, a microcircuit and a microfluidic device. Even more preferably, the optoelectronic device is an OLED.

The present invention now will be described in more detail with reference to the accompanying drawings in which:

FIG. 1 shows a cross section of a typical OLED device according to the present invention;

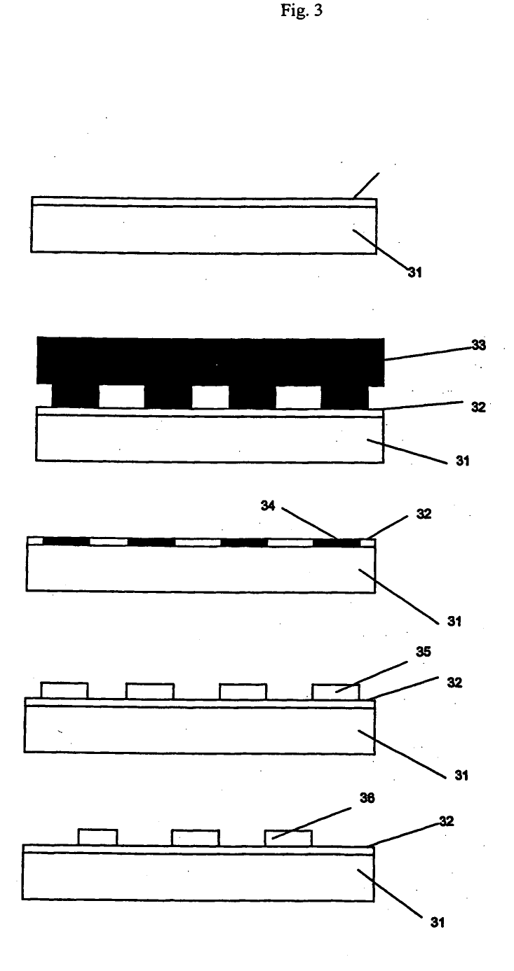

FIG. 2 shows a typical OLED device known in the art using “banks”;

FIG. 3 shows the principle of surface energy controlled patterning according to the first embodiment of the first aspect of the present invention.

FIGS. 1 and 2 clearly show the differences between a device according to the present invention and devices known in the art. In FIGS. 1 and 2, reference numeral 1 refers to a substrate; reference numeral 2 refers to an anode layer, usually ITO, that is patterned to form parallel lines running in the direction A-A′. Reference numeral 3 indicates a hole transport layer, for example PEDOT. Reference numeral 4 indicates a polymer device layer. Layer 4′ is deposited by the method according to the first aspect of the present invention to form parallel lines orthogonal to the anode lines. Layer 4″ is deposited between the banks 6. Reference numeral 5 indicates a cathode that is deposited over the polymer layer for example by shadow masking.

The principle of surface energy controlled patterning of polymers using PDMS stamp is illustrated in FIG. 3. FIG. 3 shows a film of material 32 such as PEDOT-PSS on a substrate 31 which is typically glass. PDMS stamp 33 is brought into contact with the surface of material 32. Removal of the PDMS stamp leaves areas of material 32 with modified surface properties indicated by 34. A layer of conjugated polymer is then deposited upon the modified surface of material 32, deposition may be by, for example, spin coating or dip coating. Depending on the nature of the film of material 32 and the nature of the conjugated polymer which is deposited. Deposition of the conjugated polymer may result in a positive patterned area of conjugated polymer 35 or negative patterned area of conjugated polymer 36.

Following is the description and characteristic measurement of one processing procedure according to the first embodiment of the method according to the first aspect of the present invention.

Preparation of poly (dimethylsiloxane) PDMS stamp:Two parts of Sylgard 184 silicone elastomer (Dow Corning Corp.), base and curing agent with ratio of 10:1 in mass, are mixed together in a container. This is followed by degassing of the mixture in a vacuum chamber until air bubbles no longer rise to the top. To avoid air inclusion, it is necessary to slowly pour the mixture on a template that has SU 8 (Micro Chem Corp.) photoresist patterns generated by normal photolithography, on a silicon wafer. Curing of the elastomer is done at 140° C. in an oven for 15 minutes. A PDMS stamp is ready to be used for surface modification.

Modification of surface: To modify a film surface, the PDMS stamp is brought in conformal contact with the film surfaces. Samples are kept at room temperature and with ambient humidity. The contacting time of modification is 2 days.

Poly (3,4-ethylenedioxythiophene)-poly (styrenesulfonate) (PEDOT-PSS) and poly (sodium 4-styrenesulfonate) sodium salt (NaPSS) films are formed by spin coating from their aqueous solution. Standard PEDOT-PSS solution is a water dispersion (purchased from Bayer), 1.3% concentration in mass; NaPSS solution is prepared by dissolving compounds NaPPS (Aldrich), into deionized water with concentration of 1% in mass; The spinning speed to deposit above films is 3000 rpm and 2000 rpm, giving ˜700 Å thickness of these two films, respectively. The conjugated polymer film is formed on glass substrates with spin coating from organic solutions of the polymer, in which xylene, or chloroform is used as solvent. The concentration of the polymer solution is 1.4% in mass in general. Modifying these surfaces is done by bringing a flat or structured stamp in conformal contact with surface for time periods of up to 2 days.

Contact angle is determined as the stamp is removed from the modified surface. Contact angle measurement: Contact angle measurement is performed on a contact angle goniometer (Model 100-00) at room temperature (T-21°) and ambient humidity. By using the Model 100-10 micro syringe attachment, a pendant drop above measuring surface for 1 mm, is dispensed onto the surface. A non-polar organic solvent, N-hexadecane is used as test liquid.

In order to determine the optimal modification time for a perfect pattern, the relation between contact angles and modification time are investigated.

Morphology measurement with atomic force microscope: The topography of modified film surfaces are measured by an atomic force microscope (AFM) (Nanoscope III, Digital Instruments). PEDOT-PSS and NaPSS film are deposited on a glass substrate by spin coating. The surfaces of these films are modified by patterned PDMS stamp, and the modification time is two days. After the stamp is removed, the topography is investigated by AFM. In this study, the stamps applied on the surfaces have pattern pitch/period of 22 μm, barrier rib, barrier gap are 14 μm and μm in width, respectively. It is not possible to distinguish any difference between the modified and unmodified surface areas by the naked eye or through an optical microscope.

Time Profile of Modification: The contact angle of PEDOT-PSS before modification is around 36° and that for NaPSS is about 9°, respectively. This indicates that the surface energy of PEDOT-PSS before modification by a PDMS stamp is lower than that of NaPSS. Liquids wet and spread on NaPSS film more easily than on the PEDOT-PSS film before surface modification takes place.

The contact angle of hexadecane on PEDOT-PSS or NaPSS is dramatically changed after surface modification by PDMS stamp. This change is time dependent. The contact angle on PEDOT-PSS decreases linearly from 22° to 12_20 with modification time from 25 min. to 100 hrs. For NaPSS, contact angles increase linearly from 270 to 330 with logarithmic modification time from 25 min. to 100 hrs. During the first four hours the contact angles rapidly change, but then slow down until they approach a steady value.

The changes in surface energy by modification with PDMS stamp are significant. After modification, the surface energy of PEDOT-PSS is reduced, but that of NaPSS is increased. Consequently, polymer solution with organic nonpolar solvent wets and spreads and finally covers a modified PEDOT-PSS film surface. On the modified NaPSS film surface, the liquid wets the unchanged areas. The difference in contact angle between modified and unmodified film is 25° for PEDOT-PSS film, and slightly smaller for NaPSS case, 23°. We suggest that this surface energy difference on a surface will influence the confinement of liquids. The polymer solution selectively wets and spreads only on the area with higher surface energy, controlled by surface energy difference for minimization of the surface energy of the entire system. Spin coating or dip coating polymer solution on such a modified surface can generate a positive or negative pattern depending on the character of surface energy after the modification. A positive pattern might be generated as the surface energy of the film increases after modification; when the surface energy is increased by modification, the confinement generates a negative pattern. A conjugated polymer can be patterned on the modified PEDOT-PSS film surface by dip coating or spin coating from solution.

The surface morphology has been imaged with AFM in tapping mode. Both height and phase images of PEDOT-PSS and NaPSS surface show a periodicity that is consistent with that of stamp with a bulge line along the boundary of the area where the surface has been contacted with stamp. The height of this bulge line on NaPSS surface is determined to be 30 nm, while the height on the PEDOT-PSS surface along the boundary of stamped areas is very small.

The variation of height between the stamped area and not stamped area can be negligible except for the bulge line at the boundary of the stamped area, indicating that no bulk material is transferred from the stamp to the surface during the process. The bulge may be caused by a larger interaction force between the patterned elastomer and the surface of substrate due to the higher pressure existing at the edge of the patterned elastomer contact area. It cannot be excluded that these bulges help in confining the polymer solution to certain areas in later processing steps. However, the AFM images tell us that surface energy rather than topography directs the polymer solution to the desired areas.

Infrared reflection-absorption spectra (IRAS) measurements: IRAS is used to chemically characterize the modified surface.

Substrates are prepared by thermally evaporating Cr (4.4 nm) and Au (150 nm) on cleaned silicon wafers at vacuum lever of 2*10⁻⁷ Torr. There follows a standard cleaning process, substrates are boiled in TLi solution (5:1:1H₂O, NH₃.H₂O and H₂O₂ in volume) at 90° for 15 min. Subsequently a PEDOT-PSS and a NaPSS layer is formed by spin coating on separate substrates with speed 5000 and 4000 rpm, respectively, their thickness are less than 40 nm.

The surface modification is done by bringing two flat stamps in conformal contact with PEDOT-PSS and NaPSS surface for 2 days. After removing stamps the modified PEDOT-PSS and NaPSS surfaces are obtained. A Bruker IFS 113v FTIR spectrometer with a grazing angle accessory aligned at 85°-incidence angle is employed. In order to analyze the changes in chemical compounds on the surface modified by PDMS stamp, the IRAS of pure Au, PEDOT-PSS, NaPSS and modified PEDOT-PSS and NaPSS surface are measured.

Except CO₂ and H₂O vibration bands, all vibration peaks observed are corresponding to —CH₃, and —C—Si—, which definitely originate from PDMS molecule but not from PEDOT-PSS and NaPSS molecule, revealing that materials from PDMS stamp has transferred onto PEDOT-PSS and NaPSS surface during PDMS stamp modification. However this is evidence of the transfer of chemical groups from the stamp rather than evidence of transfer of bulk material from the stamp.

Without wishing to be bound by theory it is considered that during PDMS stamp surface modification the polar group —CH₃ tails in PDMS, which are hydrophobic and with higher surface energy, prefer to link with the PEDOT-PSS surface which is more hydrophilic and has a higher surface energy before modification (contact angle of n-hexadecane on the surface without surface modification θ₁=36°). This leads —OSi— bonds stand on the top surface when the PDMS stamp is removed from the substrate, resulting in the PEDOT-PSS surface being modified from high to low surface energy, and contact angle on modified surface reducing to θ₂=90° Similarly, during modification of NaPSS by PDMS stamp the —C—Si— group of the PDMS molecule prefers to link to the NaPSS surface due to the low surface energy of the NaPSS film and the —C—Si— group being more hydrophilic, resulting in —CH₃ tails having more freedom of movement and facing upwards on the NaPSS surface. This is considered to be the reason why PDMS modification turns NaPSS surface energy from low to high, therefore increasing the contact angle from θ₃10° to θ₄=33°.

Surface energy controlled patterning of polymer: The deposition and patterning of conjugated polymer on the modified PEDOT-PSS and NaPSS surface can be achieved by dip coating or spin coating from the organic solution. Photographs of polymer patterns deposited on these modified surfaces are taken by a reflective or an inverted transmission microscope equipped with a digital camera (Sanyo, colour camera), under white light or under UV irradiation, The photoluminescence emission from conjugated polymer gives a high contrast image.

A patterned film is prepared by dip coating or spin-coating a semiconducting conjugated polymer xylene solution on a PEDOT-PSS surface modified by a stamp. The pattern positively copies stamp structure, which is consistent with the contact angle measurements. The pattern deposited can be in the form of for example squares, rectangles or thick lines, according to the stamp structure. A line pattern is deposited by dip coating on modified PEDOT-PSS surface. A photograph taken under normal illumination reveals that the patterned line is 40 μm in width, separated by 5 μm gap between lines. A square-shape pattern is generated by spin coating a light emitting conjugated polymer (a blend of a polyfluorene-benzothiadiazole copolymer and a polyfluorene-triarylamine copolymer) from xylene solution on a modified PEDOT-PSS surface. Photographs may be taken under the illumination of UV light (365 nm). The side of the squares can be in range from 50 μm to 250 μm long, spacing with 25 μm to 200 μm.

A conjugated polymer was deposited by dip coating the polymer solution on a modified NaPPS surface. The NaPPS surface was modified by contact with a PDMS stamp having a relief pattern of rectangles, the side of rectangleses being 100 μm and 200 μm, with the spacing between adjacent rectangleses being 200 μm. The pattern generated on the modified NaPSS surface is the negative of the pattern of the stamp, meaning that the polymer solution finally settles on areas that have not been in contact with the PDMS stamp. These areas having higher surface energy compared with that of areas brought into contact with the stamp. This result is opposite to the results of patterning of the conjugated polymer onto a modified PEDOT-PSS surface.

1. A method for patterning a device layer using a patterned stamp, comprising the steps of:
(a) providing a substrate;
(b) bringing the patterned stamp into contact with the substrate;
(e) removing the patterned stamp from the substrate;
(d) depositing a solution of a device layer on the substrate after the patterned stamp has been removed; whereby the surface energy of the substrate determines the deposition pattern of the device layer
wherein step (b) is carried out so that the surface energy of the substrate is modified in accordance with the pattern.

2. (canceled)

3. (canceled)

4. A method according to claim 1, wherein the topography of the surface of the substrate is unchanged after the patterned stamp has been brought into contact with the substrate.

5. A method according to claim 1 comprising depositing the device layer is by spin coating or inkjet printing.

6. A method according to claim 1, wherein the solvent is selected from the group consisting of xylene, ortho-xylene, toluene, benzene, mesitylene, chloroform, dichloromethane, and mixtures thereof.

7. (canceled)

8. A method according to claim 1, wherein in step (b) the surface energy in step (b) of any portion of the surface of the substrate that is in contact with the pattern stamp is modified.

9. A method according to claim 8, wherein the substrate comprises a polymer.

10. A method according to claim 9, wherein the polymer is poly (3,4-ethylenedioxythiophene) or polyaniline.

11. A method according to claim 8 to 10, wherein the substrate is charged.

12. (canceled)

13. A method according to any one of claims 1 to 7, wherein the patterned stamp is used as a mask in step (b) and step (b) includes subjecting any portion of the surface of the substrate that is not in contact with the patterned stamp to a surface energy modifying process.

14. A method according to claim 13, wherein the surface energy modifying process includes a step of exposing any portion of the surface of the substrate that is not in contact with the patterned stamp to UV radiation.

15.-23. (canceled)
